(19) United States
(12) Patent Application Publication
(10) Pub. No.: US 2010/0096609 A1
(43) Pub. Date: Apr. 22, 2010

(54) PHASE CHANGE MEMORY DEVICE HAVING A LAYERED PHASE CHANGE LAYER COMPOSED OF MULTIPLE PHASE CHANGE MATERIALS AND METHOD FOR MANUFACTURING THE SAME

(76) Inventors: Jin Hyock KIM, Gyeonggi-do (KR); Kee Jeung LEE, Gyeonggi-do (KR); Deok Sin KIL, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/493,672

(22) Filed: Jun. 29, 2009

(30) Foreign Application Priority Data
Oct. 21, 2008 (KR) 10-2008-0103287

(51) Int. Cl. H01L 47/00; H01L 21/00

(52) U.S. Cl. 257/2; 438/482; 257/E47.001; 257/E21.001

(57) ABSTRACT

A phase change memory device that has a layered phase change layer composed of multiple phase change materials is presented. The device includes a semiconductor substrate, an interlayer dielectric layer, a high-temperature crystallization phase change, a low-temperature crystallization phase change layer, and an upper electrode. The interlayer dielectric layer formed on the semiconductor substrate and the high-temperature crystallization phase change layer is formed on the interlayer dielectric layer. The low-temperature crystallization phase change layer is formed over the high-temperature crystallization phase change layer. The upper electrode is formed over the low-temperature crystallization phase change layer. An optional diffusion barrier may be interposed between the two phase change layers.

### CROSS-REFERENCES TO RELATED APPLICATION

The present application claims priority under 35 U.S.C. 119(a) to Korean application number 10-2008-0103287, filed on Oct. 21, 2008, in the Korean Patent Office, which is incorporated by reference in its entirety as if set forth in full.

### BACKGROUND OF THE INVENTION

1. Technical Field

The embodiments described herein relate to a memory device and a method for manufacturing the same and, more particularly, to a phase change memory device having a chalcogenide material and a method for manufacturing the same.

2. Related Art

Recently, the main issue in a semiconductor industrial field is early development and commercialization of a system on a chip (SOC) technique. In particular, prior to developing the SOC technique, a number of research studies have been actively pursued in the hopes of finding effective ways to develop the combination of a logic device and a memory device.

However, there exist a number of difficulties that one encounters when integrating together memory devices with logic devices. In particular, manufacturing problems arise when DRAMs and flash memory devices are integrated with logic devices into embedded memory devices. SOC memory devices have become important players in mobile applications because they provide several desirable properties such as a non-volatility, low-power driving, a fast operating speed, high integration, and low product cost. The DRAMS, which are representative memory devices, are well known as volatile memory devices that lose recorded data when the power is shut off. DRAMS also require refresh voltages to be applied which means that continued power consumption is expected even when DRAMS are in a stand-by state. In contrast, flash memory devices, which are well known non-volatile memory devices, do not require refresh operations, and thereby provide a number of advantages in terms of integration. However, the flash memory devices provide a number of disadvantages such as they require high voltages in order to write data and they exhibit low operating speeds. In addition, flash memory devices suffer the disadvantage of having a finite number of write/read operations.

Accordingly, research studies have continued to develop 2o non-volatile memory devices suitable for the SOC technique applications as well as to develop single memories while overcoming the limitations suffered from DRAMS and flash memory devices. In this regard, recently research studies have been intensively actively pursued approaches that include ferroelectric random access memories (FeRAM), phase change RAM (PRAM) devices and magnetoresistive random access memories (MRAM).

Unfortunately, FeRAMs suffer a disadvantage in that it is very difficult to minimize functional FeRAMs to suit the needs of increased integration. That is, miniaturized FeRAMs are prone to suffering deterioration of their respective performance characteristics when repeatedly performing write/read operations. MRAMs suffer a disadvantage in that they have a small sensing margin insufficient to read data, and MRAMs also requires a digit line. In addition, when MRAMs are integrated into highly compact chips, inter-cell interference is known to occur which frustrates highly integrated MRAM designs. In contrast, PRAMs offer a number of advantages such as they have a simple structure, and they suffer little or no inter-cell interference. Accordingly, PRAMs can be highly integrated. It is also generally known in the art that the PRAM provides the advantage of high speed operations because the PRAMs can perform fast read speed (several tens of nanoseconds) and the faster write speeds (several tens to several hundreds of nanoseconds).

In addition, since PRAMs can be easily incorporated with the manufacturing process for the CMOS logic, then their manufacturing cost thereof can be reduced. Accordingly, the PRAM is regarded as a memory of choice because it offers a high possibility in terms of commercialization.

Meanwhile, in order to make a PRAM-based product and introduce the product into a memory market, the cell size of the PRAM must be reduced, i.e., integrated. Furthermore, the reliability for the PRAM must be improved so that the PRAM has a low manufacturing cost and is in a highly integrated form. In the ideal highly integrated case of a PRAM, the PRAM can be scaled down to the level of about a 20 nm-node and the unit cell of the ideal PRAM may be realized in the size of at least 6F², where F is understood to be the minimum feature size.

However, the most restrictive factor against using PRAMs seems to be that they require high currents of up to about 1 mA for driving reset state transitions. When considering that a transistor for a logic device usually has an allowable current of about 0.05 mA/0.1 μm, the current value of the PRAM of about 1 mA makes it difficult to reduce the size of the transistor. Actually, 64 Mb-PRAMs have a cell size of 15F² under a design rule of 0.18 μm, which is greatly different from an ideal cell size.

Therefore, in order to develop highly-integrated PRAMs, a reset current must be reduced. In this regard, a number of research studies have been carried out with the design towards reducing the reset current of PRAMs. In this case, the reset current of PRAMs is dependent upon a number of factors. These factors include the particular GeSbTe chalcogenide, which is a phase change material, the contact area with an electrode, the particular structure, the resistance of the GST, the size, the thickness, and the adiabatic properties.

Among the above factors, the resistance of the GST (a phase change layer) and the electrode may be easily changed in order to lower the reset current. In this case, the phase change of the GST is induced by using Joule heat caused by electric pulses. If the resistance of the GST or the electrode is increased, the Joule heat is also increased, so that the reset current can be lowered. In addition, when the GST is deposited in an atmosphere of an argon (Ar) gas including nitrogen (N), the resistance of the GST can be increased. Actually, a PRAM device employing a GST doped with N can operate with a reset current of about 0.6 mA at 50 ns and a set current of about 0.2 mA at 100 ns.

Recently, the GST has been developed based on the composition ratio of the Ge, Sb, Te components which have been mixed in the composition ratio of about 2:2:5. Although such materials provide a number of advantages such as stability, low current consumption, and fast phase change, these types of materials suffer low retention characteristics brought about by their low crystallization temperature (˜150° C.). In addition, when these H materials form into the ordered crystalline solid phase, these materials may have either face centered cubic (FCC) or hexagonal close packed (HCP) structures. As a result these materials may have variable resistivities which are dependent upon which type of ordered crystalline solid phase.

### SUMMARY

According to one embodiment, a phase change memory device includes a semiconductor substrate including a heating electrode, a first phase change layer formed on the semiconductor substrate to receive heat from the heating electrode, a second phase change layer formed on the first phase change layer, and an upper electrode formed on the second phase change layer, wherein a crystallization temperature of the first phase change layer is higher than that of the second phase change layer.

According to another embodiment, a phase change memory device includes a semiconductor substrate including a switching device, an interlayer dielectric layer formed on the semiconductor substrate, and including a heating electrode electrically connected with the switching device, main and auxiliary phase change layers sequentially stacked on the interlayer dielectric layer, an upper electrode formed on the main phase change layer, and a diffusion barrier interposed between the main and auxiliary phase change is layers.

According to still another embodiment, a phase change memory device includes a semiconductor substrate including a switching device, an interlayer dielectric layer formed on the semiconductor substrate, and including a heating electrode electrically connected with the switching device, a high-temperature crystallization phase change layer formed on the interlayer dielectric layer, a diffusion barrier formed on the high-temperature crystallization phase change layer, a low-temperature crystallization phase change layer formed on the diffusion barrier at a thickness thicker than a thickness of the high-temperature crystallization phase change layer, and an upper electrode formed on the low-temperature crystallization phase change layer.

According to still another embodiment, a method for manufacturing a phase change memory device includes preparing a semiconductor substrate including a switching device, forming an interlayer dielectric layer including a heating electrode on the semiconductor substrate, forming an auxiliary phase change layer on the interlayer dielectric layer, forming a main phase change layer on the auxiliary phase change layer, and forming an upper electrode on the main phase change layer.

These and other features, aspects, and embodiments are described below in the section entitled “Detailed Description.”

### BRIEF DESCRIPTION OF THE DRAWINGS

The above and other embodiments, features and other advantages of the subject matter of the present disclosure will be more clearly understood from the following detailed description taken in conjunction with the accompanying drawings, in which:

FIGS. 1 to 4 are sectional views a manufacturing process of a phase change memory device according to one embodiment of the disclosure; and

FIG. 5 is a sectional view showing a phase change memory device according to another embodiment of the disclosure.

### DETAILED DESCRIPTION

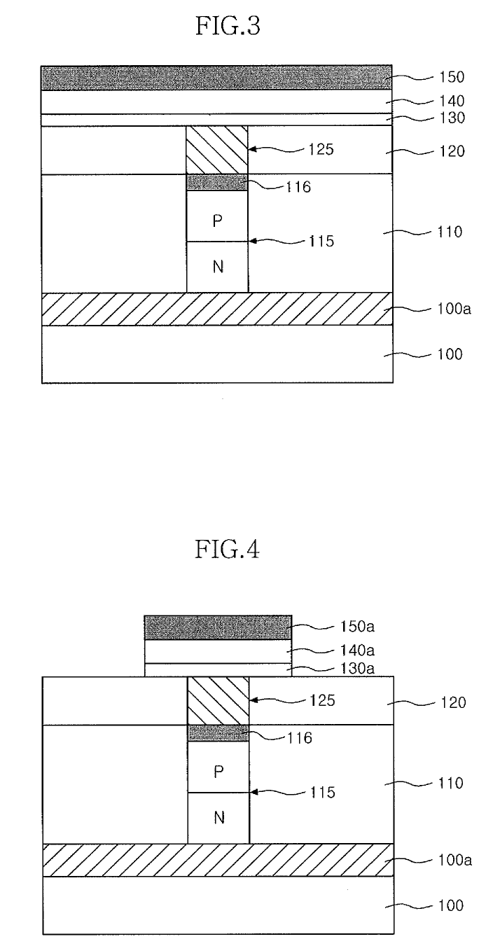

FIGS. 1 to 4 are sectional views the manufacturing process of a phase change memory device according to one embodiment of the disclosure. It is understood herein that the drawings are not necessarily to scale and in some instances proportions may have been exaggerated in order to more clearly depict certain features of the invention.

First, referring to FIG. 1, an impurity area 100a is formed on a predetermined portion of a semiconductor substrate 100 and eventually serves as a word line of the phase change memory device. If the semiconductor substrate 100 is a p-type substrate, the impurity area 100a may be implanted with n-type impurities, and vice versa. Next a first interlayer dielectric layer 110 is formed over an upper portion of the semiconductor substrate 110. The first interlayer is dielectric layer 110 may for example include an oxide or a complex layer of an oxide and a nitride. The oxide may be formed using a tetra ethyl ortho silicate (TEOS), an undoped silicate glass (USG), or a high density plasma-CVD (HDP-CVD).

The first interlayer dielectric layer 110 is subsequently selectively etched to expose a predetermined portion of the impurity area 100a to thereby form a contact hole (not shown). Afterwards a switching element 115 is formed within the contact hole. The switching element 115 may be a PN diode switching element 115. The PN diode 115 may be formed by using a selective epitaxial growth (SEG) scheme generally known in the art. An ohmic-contact layer 116 is then formed over the PN diode 115. The ohmic-contact layer 116 may be formed using a metal silicide material.

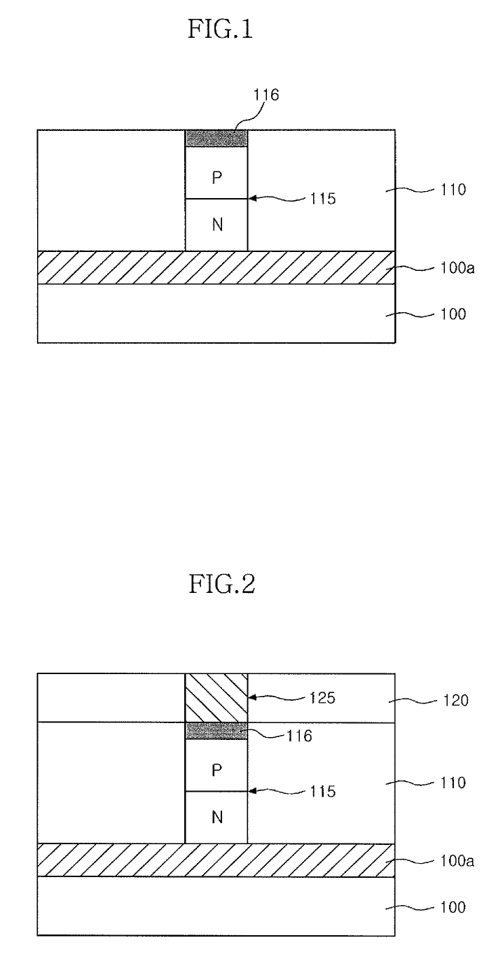

Referring to FIG. 2, a second interlayer dielectric layer 120 is then formed over the first interlayer dielectric layer 110 which has the PN diode 115 formed within it. Thereafter, the ohmic-contact layer 116 is exposed by selectively etching away a predetermined portion of the second interlayer dielectric layer 120 to form a heating electrode contact hole (not shown). Next, the heating electrode contact hole is filled in with a conductive layer to thereby form a 10 heating electrode 125. The heating electrode 125 may be formed by using a conductive layer having high resistivity, such as a polysilicon layer doped with impurities, a silicon germanium (SiGe) layer or a titanium nitride (TiN) layer.

Referring to FIG. 31 a first phase change layer 130 and a is second phase change layer 140 are sequentially formed over the second interlayer dielectric layer 120. The first phase change layer 130 preferably includes a phase change material having a crystallization temperature higher than that of the second phase change layer 140. According to the embodiment, the first phase change layer 130 may include a germanium-antimony (GeₓSb₍₁₋ₓ₎ where 0<x<1) compound layer having a thickness of about 20 Å to 500 Å. The stoichiometric composition ratio (x) of the Ge in the GeₓSb₍₁₋ₓ₎ is between 0 to 1, and preferably between 0.1 to 0.3.

The first phase change layer 130 may include the GeₓSb₍₁₋ₓ₎ compound layer formed using any number of different techniques such as physical vapor deposition (PVD) scheme, a chemical vapor deposition (CVD) scheme, or an automatic layer deposition (ALD). When the first phase change layer 130 must be formed in a three-dimensional structure, the CVD scheme having a superior deposition characteristic is preferred. In addition, when the first phase change layer 130 is formed through the CVD scheme, a rapid thermal annealing (RTA) process or a furnace annealing process may also be performed in order to improve the compositional uniformity and stability of the first phase change layer 130. The annealing processes may be performed in a reducing atmosphere composed of nitrogen (N₂), hydrogen (H₂), argon (Ar) or the mixture thereof to prevent the GeₓSb₍₁₋ₓ₎ compound layer of the first phase change layer 130 from being oxidized. In addition, the annealing processes may be performed at a relatively low temperature of about 300° C. to 400° C. to prevent or protect against Ge or Sb from being volatilized.

The second phase change layer 140 includes a chalcogenide compound as a main phase change material, and is deposited at a thickness of about 100 Å to 2000 Å.

The chalcogenide compound of the second phase change layer 140 may include one of chalcogenide alloys such as a germanium-antimony-tellurium (Ge—Sb—Te) alloy, a nitrogen-germanium-antimony-tellurium (N—Ge—Sb—Te) alloy, an arsenic-antimony-tellurium (As—Sb—Te) alloy, a germanium-bismuth-tellurium (Ge—Bi—Te) alloy, a tin-antimony-tellurium (Sn—Sb—Te) alloy, a silver-indium-antimony-tellurium (Ag—In—Sb—Te) alloy, a gold-indium-antimony-tellurium (Au—In—Sb—Te) alloy, a germanium-indium-antimony-tellurium (Ge—In—Sb—Te) alloy, a selenium-antimony-tellurium (Se—Sb—Te) alloy, a tin-indium-antimony-tellurium (Sn—In—Sb—Te), and an arsenic-germanium-antimony-tellurium (As—Ge—Sb—Te) alloy.

According to another example, the chalcogenide compound of the second phase change layer 140 may include a 5A-group element-antimony-tellurium alloy such as a tantalum-antimony-tellurium (Ta—Sb—Te) alloy, or a niobium-antimony-tellurium (Nb—Sb—Te) alloy, or a vanadium-antimony-tellurium (V—Sb—Te) alloy. The chalcogenide compound may include a 5A-group element-antimony-selenium such as a tantalum-antimony-selenium (Ta—Sb—Se) alloy, a niobium-antimony-selenium (Nb—Sb—Se) alloy, or a vanadium-antimony-selenium (V—Sb—Se). In addition, a phase change material is layer of the second phase change layer 140 may also include a 6A-group-antimony-tellurium alloy such as a tungsten-antimony-tellurium (W—Sb—Te) alloy, a molybdenum-antimony-tellurium (Mo—Sb—Te) alloy, or a chromium-antimony-tellurium (Cr—Sb—Te) alloy. The phase change material layer may include a 6A-group-antimony-selenium alloy such as a tungsten-antimony-selenium (W—Sb—Se) alloy, a molybdenum-antimony-selenium (Mo—Sb—Se) or a chromium-antimony-selenium (Cr—Sb—Te) alloy. A chalcogenide thin film of the second phase change layer 140 may include various kinds of dopants such as nitrogen (N) or an oxide material (SiO₂).

According to the embodiment, the germanium-antimony-tellurium (Geₓ—Sb_{y}—Te_{z}) alloy may be used to form the second phase change layer 140, and having a preferred stoichiometric composition ratio (x:y:z) of the Geₓ—Sb_{y}—Te_{z} of about 2:2:5, respectively.

In such a double layer structure composed of the first and second phase change layers 130 and 140, the first phase change layer 130 which includes the relatively thin Ge—Sb layer is formed below the thicker second phase change layer 140. As a result the double layer structure provides the advantage of a low crystallization temperature and provides an effective crystallization temperature of the whole phase change layer can be increased by a predetermined value. Thereby the double layer structure composed of the first and second phase change layers 130 and 140 ensures a more reliable data retention characteristic because the crystallization temperatures are relatively high and less prone unwanted crystallization driven by ambient conditions.

Next, an upper electrode layer 150 is formed over the second phase change layer 140. The upper electrode layer 150 is formed by using a conductive material including N, metal, or metal silicide. The conductive material including N may include titanium nitride (TiN), tantalum nitride (TaN), molybdenum nitride (MoN), niobium nitride (NbN), titanium silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium oxynitride (TiON), titanium aluminum oxynitride (TiAlON), tungsten oxynitride (WON), or tantalum oxynitride (TaON).

Thereafter, referring now to FIG. 4, the upper electrode 150a, the second phase change pattern 140a and the first phase change pattern 130a are formed by patterning predetermined portions of the upper electrode layer 150, the second phase change layer 140, and the first second change layer 130.

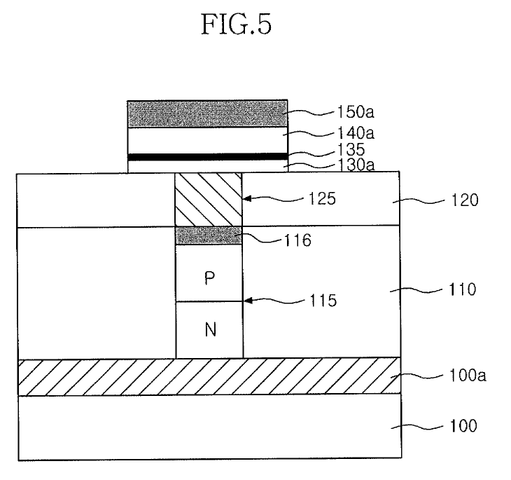

As shown in FIG. 5, a diffusion barrier 135 may be additionally interposed between the second and first phase change pattern 140a and 130a so that components of the second and first phase change patterns 140a and 130a are restrained from intermingling together brought about by diffusion processes driven by the frequent phase change operations of the second phase change pattern 140a and the first phase change pattern 130a. The diffusion barrier 135 may be formed by using a layer capable of blocking the migration of phase change components between the second and first phase change patterns 140a and 130a while applying the greater amount of heat to the second phase change pattern 140a. Such a diffusion barrier 135 may include a conductive layer such as a metal layer or a metal oxide layer capable of transferring heat. The diffusion barrier 135 may have a resistivity equal to or greater than that of the heating electrode 125. For example, the diffusion barrier 135 may include one of TiN, TiAlN, TiSiN, TaN, and TaSiN, or may have a multiple-layer structure. The diffusion barrier 135 may have a thickness of about 20 Å to 200 Å. Preferred relative thickness ratios of the first phase change pattern 130a, the diffusion barrier 135, and the second phase change pattern 140a are between about 1:0.5:4 to 1:2:4, respectively.

As described above, the first and second phase change patterns 130a and 140a may eventually have stoichiometries that are different from initial stoichiometries due to the intermingling of the components driven by the frequent phase change operations of the first and second phase change patterns 130a and 140a. Accordingly, it is understood that the first and second phase change patterns 130a and 140a may also change in terms of an electrical characteristic thereof. However, according to the present embodiment, the optional diffusion barrier 135 may be interposed between the first and second phase change patterns 130a and 140a so as to maintain the initial stoichiometries of the first and second phase change patterns 130a and 140a. Therefore, the optional diffusion barrier 135 may be aid in maintaining a consistent electrical reliability through the lifetime of the present device.

In addition, the diffusion barrier 135 may be interposed between the first and second phase change patterns 130a and 140a so that the current transfer characteristic of the second phase change pattern 140a is enhanced. Accordingly, the interposed diffusion barrier 135 may also improve the set/reset time characteristics.

Furthermore, separate current transfer path is formed for the diffusion barrier 135 are also envisioned so that the first and second phase change patterns 130a and 140a can be driven to phase change separate from each other. Accordingly, it is envisioned that the present device can be configured to realize storing multiple bits within a single memory cell of the PRAM device.

As described above in detail, phase change layers according to the disclosure are formed by additionally forming an auxiliary phase change layer (i.e., first), which preferably has a crystallization temperature higher than that of a main phase change layer (i.e., second). The auxiliary phase change layer is preferably positioned below the main phase change layer, so that data retention time can be ensured together with the stability of a phase change material, a low current consumption characteristic, and a fast response characteristic.

Furthermore, a diffusion layer may be additionally interposed between the phase change layers, thereby preventing or protecting against components of the phase change layers from being diffused between the phase change layers. Accordingly, the reliability of the phase change memory device can be more improved.

While certain embodiments have been described above, it will be understood that the embodiments described are by way of example only. Accordingly, the systems and methods described herein should not be limited based on the described embodiments. Rather, the systems and methods described herein should only be limited in light of the claims that follow when taken in conjunction with the above description and accompanying drawings.

What is claimed is:

1. A phase change memory device comprising:
a semiconductor substrate including a heating electrode;
a first phase change layer formed over the semiconductor substrate and configured to receive heat from the heating electrode;
a second phase change layer formed over the first phase change layer; and
an upper electrode formed over the second phase change layer,
wherein the first phase change layer having a crystallization temperature higher than that of the second phase change layer.

2. The phase change memory device of claim 1, wherein the first phase change layer is thinner than the second phase change layer.

3. The phase change memory device of claim 1, wherein the first phase change layer comprises a germanium-antimony GeₓSb₍₁₋ₓ₎ compound layer has a stoichiometry of between about 0<x<1.

4. The phase change memory device of claim 3, wherein the GeₓSb₍₁₋ₓ₎ compound layer having the stoichiometry of between about 0.1<x<0.3.

5. The phase change memory device of claim 1, wherein the second phase change layer comprises a chalcogenide compound.

6. The phase change memory device of claim 5, wherein the chalcogenide compound of the second phase change layer is selected from the group consisting of a germanium-antimony-tellurium (Ge—Sb—Te) alloy, a nitrogen-germanium-antimony-tellurium (N—Ge—Sb—Te) alloy, an arsenic-antimony-tellurium (As—Sb—Te) alloy, a germanium-bismuth-tellurium (Ge—Bi—Te) alloy, a tin-antimony-tellurium (Sn—Sb—Te) alloy, a silver-indium-antimony-tellurium (Ag—In—Sb—Te) alloy, a gold-indium-antimony-tellurium (Au—In—Sb—Te) alloy, a germanium-indium-antimony-tellurium (Ge—In—Sb—Te) alloy, a selenium-antimony-tellurium (Se—Sb—Te) alloy, a tin-indium-antimony-tellurium (Sn—In—Sb—Te), an arsenic-germanium-antimony-tellurium (As—Ge—Sb—Te) alloy, a tantalum-antimony-tellurium (Ta—Sb—Te) alloy, a niobium-antimony-tellurium (Nb—Sb—Te) alloy, a vanadium-antimony-tellurium (V—Sb—Te) alloy, a tantalum-antimony-selenium (Ta—Sb—Se) alloy, a niobium-antimony-selenium (Nb—Sb—Se) alloy, or a vanadium-antimony-selenium (V—Sb—Se), a tungsten-antimony-tellurium (W—Sb—Te) alloy, a molybdenum-antimony-tellurium (Mo—Sb—Te) alloy, or a chromium-antimony-tellurium (Cr—Sb—Te) alloy, a tungsten-antimony-selenium (W—Sb—Se) alloy, a molybdenum-antimony-selenium (Mo—Sb—Se), a chromium-antimony-selenium (Cr—Sb—Te) alloy and admixtures thereof.

7. The phase change memory device of claim 1, further comprising a diffusion barrier interposed between the first phase change layer and the second phase change layer.

8. The phase change memory device of claim 7, wherein the diffusion barrier comprises a material that conducts electrical current and substantially blocks intermingling between components of the first and second phase change layers.

9. The phase change memory device of claim 7, wherein the 10 diffusion barrier comprises either a metal layer or a metal oxide layer.

10. The phase change memory device of claim 7, wherein the diffusion barrier includes a material having resistivity substantially equal to or greater than resistivity of the heating electrode.

11. The phase change memory device of claim 7, wherein the diffusion barrier composed of material selected from the group consisting of titanium (Ti), titanium nitride (TiN), titanium aluminum nitride (TiAlN), tantalum (Ta), tantalum nitride (TaN), and tantalum silicon nitride (TaSiN).

12. A phase change memory device comprising:
a semiconductor substrate including a switching device;
an interlayer dielectric layer formed over the semiconductor substrate, the interlayer dielectric layer including a heating electrode electrically connected with the switching device;
main and auxiliary phase change layers sequentially stacked over the interlayer dielectric layer;
an upper electrode formed on the main phase change layer; and
a diffusion barrier interposed between the main and auxiliary phase change layers.

13. The phase change memory device of claim 12, wherein the diffusion barrier includes either a metal layer or a metal oxide layer.

14. The phase change memory device of claim 12, wherein the diffusion barrier has a resistivity substantially equal to or greater than resistivity of the heating electrode.

15. The phase change memory device of claim 12, wherein the diffusion barrier is selected from the group consisting of titanium (Ti), titanium nitride (TiN), titanium aluminum nitride (TiAlN), tantalum (Ta), tantalum nitride (TaN), and tantalum silicon nitride (TaSiN).

16. A phase change memory device comprising:
a semiconductor substrate including a switching device;
an interlayer dielectric layer formed on the semiconductor substrate, the interlayer dielectric layer including a heating electrode electrically connected with the switching device;
a high-temperature crystallization phase change layer formed over the interlayer dielectric layer;
a diffusion barrier formed over the high-temperature crystallization phase change layer;
a low-temperature crystallization phase change layer formed over the diffusion barrier, the low-temperature crystallization phase change layer being thicker than the high-temperature crystallization phase change layer; and
an upper electrode formed over the low-temperature crystallization phase change layer.

17. The phase change memory device of claim 16, wherein the high-temperature crystallization phase change layer includes a germanium-antimony GeₓSb₍₁₋ₓ₎ compound layer having a stoichiometry between about 0<x<1.

18. The phase change memory device of claim 17, wherein the GeₓSb₍₁₋ₓ₎ compound layer has the stoichiometry between about 0.1<x<0.3.

19. The phase change memory device of claim 16, wherein the high-temperature crystallization phase change layer includes a germanium-antimony-tellurium (GeSbTe) compound layer.

20. The phase change memory device of claim 19, wherein the GeSbTe compound layer having a GeₓSb_{y}Te_{z} stoichiometry where x:y:z corresponds to about 2:2:5.

21. The phase change memory device of claim 16, wherein the diffusion barrier includes a conductive layer having resistivity substantially equal to or greater than resistivity of the heating electrode.

22. The phase change memory device of claim 16, wherein the diffusion layer is composed of material selected from the group consisting of titanium (Ti), titanium nitride (TiN), titanium aluminum nitride (TiAlN), tantalum (Ta), tantalum nitride (TaN), and tantalum silicon nitride (TaSiN).

23. The phase change memory device of claim 16, wherein a thickness ratio of the high-temperature crystallization phase change layer to the diffusion barrier to the low-temperature crystallization phase change layer is between about 1:0.5:4 to 1:2:4.

24. A method for manufacturing a phase change memory device, the method comprising:
preparing a semiconductor substrate including a switching device;
forming an interlayer dielectric layer including a heating electrode on the semiconductor substrate;
forming an auxiliary phase change layer over the interlayer dielectric layer;
forming a main phase change layer over the auxiliary phase change layer; and
forming an upper electrode over the main phase change layer.

25. The method of claim 24, wherein the auxiliary phase change layer is thicker than the main phase change layer and the main phase change layer has a crystallization temperature higher than that of the auxiliary phase change layer.

26. The method of claim 24, wherein the auxiliary phase change layer is formed using anyone of a physical vapor deposition (PVD) scheme, a chemical vapor deposition (CVD) scheme, and an automatic layer deposition (ALD).

27. The method of claim 24, wherein, when the auxiliary phase change layer is formed using a CVD deposition scheme followed with an annealing process.

28. The method of claim 27, wherein the annealing process is performed at a temperature of about 300° C. to 400° C.

29. The method of claim 24, further comprising forming a diffusion layer between the auxiliary phase change layer and the main phase change layer.

30. The method of claim 29, wherein the diffusion layer is composed of material selected from the group consisting of titanium (Ti), titanium nitride (TiN), titanium aluminum nitride (TiAlN), tantalum (Ta), tantalum nitride (TaN), and tantalum silicon nitride (TaSiN).
